(19) United States
(12) Patent Application Publication
(10) Pub. No.: US 2022/0186359 A1
(43) Pub. Date: Jun. 16, 2022

(54) FIXTURE, TRAY AND SPUTTERING SYSTEM

(71) Applicant: BOE Technology Group Co., Ltd., Beijing (CN)

(72) Inventors: Nianqi YAO, Beijing (CN); Ce NING, Beijing (CN); Zhengliang LI, Beijing (CN); Hehe HU, Beijing (CN); Dapeng XUE, Beijing (CN); Lizhong WANG, Beijing (CN); Shuilang DONG, Beijing (CN); Jie HUANG, Beijing (CN); Jiayu HE, Beijing (CN); Lubin SHI, Beijing (CN); Yancai LI, Beijing (CN)

(21) Appl. No.: 17/485,170

(22) Filed: Sep. 24, 2021

(30) Foreign Application Priority Data
Dec. 10, 2020 (CN) 202022938755.X

(51) Int. Cl. C23C 14/50

(52) U.S. Cl. CPC C23C 14/50

(57) ABSTRACT

A fixture, a tray and a sputtering system. The fixture is internally provided with a support structure and a clamping structure connected with each other, wherein the clamping structure is configured to clamp a to-be-sputtered substrate; an orthographic projection of the clamping structure on a plane where the support structure is located and the support structure share an superimposed area and are separate in non-superimposed areas; wherein the support structure located in the non-superimposed area and/or the clamping structure located in the non-superimposed area has a first hollowed structure. The fixture is internally provided with the first hollowed structure, such that a part of an area of the to-be-sputtered substrate covered by the fixture may be exposed via the first hollowed structure when the fixture holds the to-be-sputtered substrate, so as to reduce the area of the to-be-sputtered substrate covered by the fixture.

### CROSS REFERENCE TO RELEVANT DISCLOSURES

The present application claims the priority of the Chinese patent application filed on Dec. 10, 2020 before the Chinese Patent Office with the application number of 202022938755.X and the title of “FIXTURE, TRAY AND SPUTTERING SYSTEM”, which is incorporated herein in its entirety by reference.

### TECHNICAL FIELD

The disclosure relates to the technical field of sputtering, in particular to a fixture, a tray and a sputtering system.

### BACKGROUND

In the industry of display panel manufacturing, a coating device mainly adopts a magnetron sputtering method and a chemical vapor deposition method during coating. To increase the production efficiency, more and more large-sized displaying substrates have emerged. During manufacturing of the large-sized displaying substrates, the magnetron sputtering method generates films in vertical film forming way.

In the vertical film forming process, to ensure the safety of a to-be-sputtered substrate, the to-be-sputtered substrate is placed on a tray provided with a plurality of fixtures. The to-be-sputtered substrate is fixed on the tray by the fixtures to ensure the safety of the to-be-sputtered substrate in the coating process.

### SUMMARY

The embodiments of the disclosure provide a fixture, a tray and a sputtering system.

The embodiments of the disclosure disclose a fixture, comprising a support structure and a clamping structure connected with each other, wherein the clamping structure is configured to clamp a to-be-sputtered substrate; both a superimposed area and a non-superimposed area exist between an orthographic projection of the clamping structure on a plane where the support structure is located and the support structure;

wherein the support structure located in the non-superimposed area and/or the clamping structure located in the non-superimposed area has a first hollowed structure.

Optionally, the clamping structure comprises a first clamping component, a second clamping component, and a connecting component which connects the first clamping component and the second clamping component; a plane where the first clamping component is located is parallel to a plane where the second clamping component is located, and the plane where the first clamping component is located and the plane where the second clamping component is located are perpendicular to a plane where the connecting component is located.

Optionally, the first hollowed structure is located in the clamping structure, and penetrates through the first clamping component in the clamping structure.

Optionally, the first hollowed structure is located in the support structure;

wherein, the first clamping component comprises at least one clamping sub-component, each of the clamping sub-components is connected with the support structure, and an orthographic projection of each of the clamping sub-components on the plane where the support structure is located is not superimposed with the first hollowed structure in the support structure.

Optionally, an extension direction of each of the clamping sub-components is parallel or perpendicular to an extension direction of the support structure.

Optionally, the first clamping component comprises at least two clamping sub-components, and on the plane where the support structure is located, all the clamping sub-components of the first clamping component are located on a same side of the first hollowed structure, or the first clamping sub-components of the first clamping component and second clamping sub-components other than the first clamping sub-components in the first clamping component are located on different sides of the first hollowed structure.

Optionally, the support structure and the clamping structure which are located in the superimposed area have a second hollowed structure, and the second hollowed structure penetrates through the support structure and the clamping structure.

Optionally, a hollowing rate of the fixture is greater than or equal to 50% and less than 100%.

Optionally, a width of the first clamping component is greater than a width of the second clamping component in the extension direction of the support structure.

Optionally, in the extension direction of the support structure, the width of the first clamping component is 10 mm-30 mm, and the width of the second clamping component is 1 mm-5 mm; and,

a thickness of the connecting component is 1 mm-5 mm along a direction perpendicular to the plane where the first clamping component is located.

Optionally, the first hollowed structure and the second hollowed structure are both closed structures.

The embodiments of the disclosure further disclose a sputtering system, comprising a sputtering device and a tray.

### BRIEF DESCRIPTION OF THE DRAWINGS

To describe the technical solutions in the embodiments of the disclosure more clearly, the drawings required for describing the embodiments of the disclosure will be simply introduced below. Obviously, the drawings depicted below only illustrate some embodiments of the application. Other drawings may further be obtained by a person of ordinary skill in the art according to these drawings without creative work.

FIG. 1 illustrates a schematic diagram of a sputtering process performed on a to-be-sputtered substrate in the related art;

FIG. 2 illustrates a planar diagram of a fixture in the related art;

FIG. 3 illustrates a planar diagram of a fixture according to the embodiments of the application;

FIG. 4 illustrates a planar diagram of another fixture according to the embodiments of the application;

FIG. 5 illustrates a lateral view of the fixture in FIG. 3;

FIG. 6 illustrates a lateral view of the fixture in FIG. 4;

FIG. 7 illustrates a planar diagram of another fixture according to the embodiments of the application;

FIG. 8 illustrates a schematic diagram of resistance of film layers obtained using fixtures of different hollowing rates; and

FIG. 9 illustrates a schematic diagram of a tray according to the embodiments of the application.

### DETAILED DESCRIPTION

The technical solutions in the embodiments of the disclosure will be described clearly and completely in conjunction with accompanying drawings in the embodiments of the application. Apparently, the described embodiments are merely illustrative ones, and are not all possible ones of the application. All other embodiments obtained by a person of ordinary skill in the art based on the following ones without creative labor shall fall within the protective scope of the embodiments of the application.

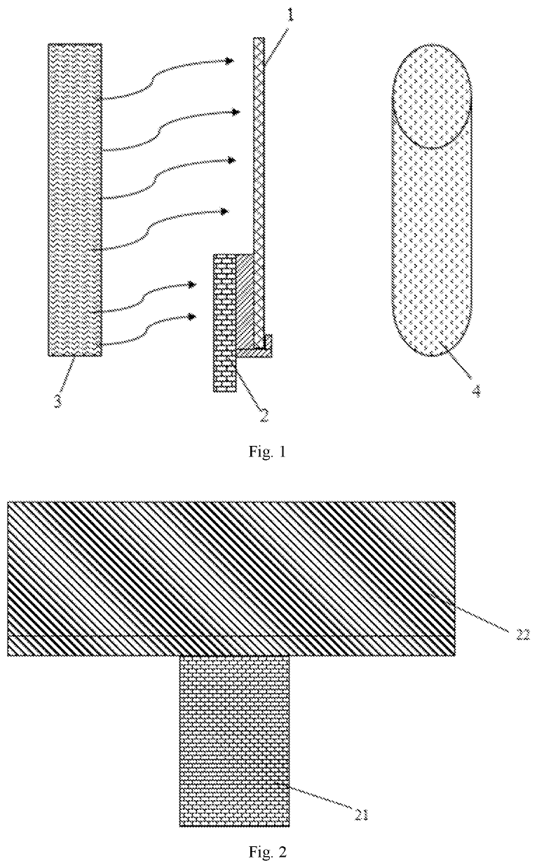

In the related art, when a sputtering device performs magnetron sputtering on a to-be-sputtered substrate using a vertical film forming method, as shown in FIG. 1, the to-be-sputtered substrate 1 is fixed by a fixture 2, a heating device 3 is located on one side of the to-be-sputtered substrate 1, and a target material 4 is located on the other side of the to-be-sputtered substrate 1. In the sputtering process, the heating device 3 needs to heat the to-be-sputtered substrate 1. The specific structure of the fixture 2 is shown in FIG. 2. The fixture 2 comprises a support structure 21 and a clamping structure 22. When the fixture 2 is used to hold the to-be-sputtered substrate 1, the clamping structure 22 in the fixture 2 covers a corresponding area of the to-be-sputtered substrate 1. Moreover, since the clamping structure 22 is usually made of a thermal insulating material, the clamping structure 22 blocks transmission of heat from the sputtering device to its covered area of the to-be-sputtered substrate 1. Therefore, during coating of the to-be-sputtered substrate 1, the film-forming temperature in the area of the to-be-sputtered substrate 1 covered by the clamping structure 22 is lower than the film-forming temperature in the area of the to-be-sputtered substrate 1 that is not covered by the clamping structure 22.

In the film forming process of the to-be-sputtered substrate 1, the film-forming temperature directly influences the quality of the formed film. The higher the film-forming temperature, the greater energy ions deposited on the to-be-sputtered substrate 1 in the ion sputtering process, the higher the compactness of the film layer deposited on the to-be-sputtered substrate 1, and finally, the better the quality of the formed film. In addition, a higher film-forming temperature leads to larger sizes of crystal particles in the formed film layer, fewer crystal boundaries, fewer flaws in the film layer, better film quality, and finally, higher product quality and product yield.

Therefore, according to the embodiments of the disclosure, in the fixture, the first hollowed structure is provided on the support structure located in the non-superimposed area and/or the clamping structure located in the non-superimposed area, such that a part of an area of the to-be-sputtered substrate covered by the fixture may be exposed via the first hollowed structure when the fixture holds the to-be-sputtered substrate, so as to reduce the area of the to-be-sputtered substrate covered by the fixture, thereby increasing the film-forming temperature in the area of the to-be-sputtered substrate covered by the fixture in the sputtering process, improving the quality of a film formed in the area of the to-be-sputtered substrate covered by the fixture, and further improving the quality and yield of products.

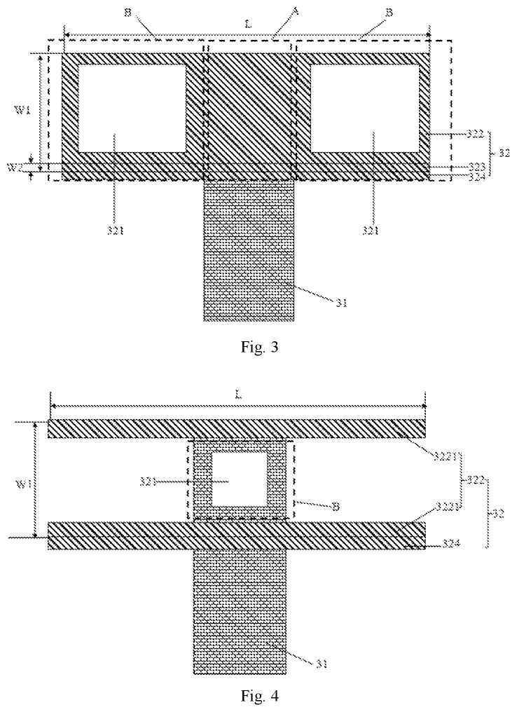

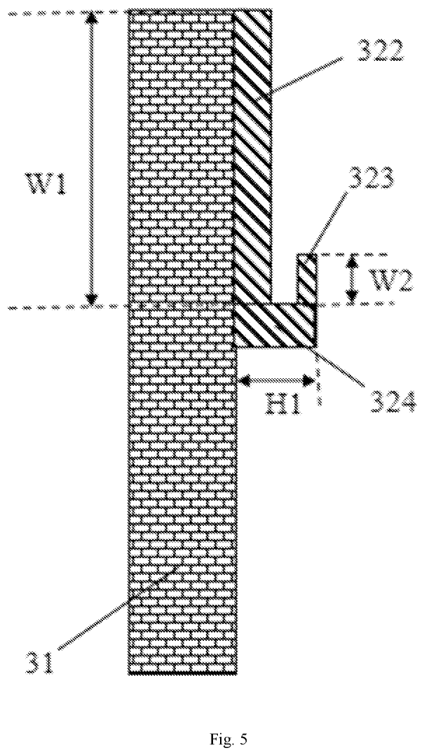

Refer to FIG. 3, which illustrates a planar diagram of a fixture according to the embodiments of the disclosure; FIG. 4 illustrates a planar diagram of another fixture according to the embodiments of the disclosure.

The embodiments of the disclosure provide a fixture, comprising a support structure 31 and a clamping structure 32 connected with each other, wherein the clamping structure 32 is configured to clamp a to-be-sputtered substrate; an orthographic projection of the clamping structure 32 on a plane where the support structure 31 is located and the support structure 31 share an superimposed area A and are separate in non-superimposed areas B; wherein the support structure 31 located in the non-superimposed area B and/or the clamping structure 32 located in the non-superimposed area B has a first hollowed structure 321.

According to the embodiments of the disclosure, a fixture is provided. The fixture is used to hold a to-be-sputtered substrate when the to-be-sputtered substrate is subject to the sputtering process so as to ensure the safety of the to-be-sputtered substrate in the sputtering process. The sputtering process may be used to form a film layer for manufacturing a data line and a signal line on the to-be-sputtered substrate, and may also be used to form an ITO (Indium Tin Oxide) film layer or an IGZO (Indium Gallium Zinc Oxide) film layer, etc. on the to-be-sputtered substrate.

According to the embodiments of the disclosure, the fixture comprises the support structure 31 and the clamping structure 32 connected with each other. As shown in FIG. 3, an orthographic projection of the clamping structure 32 on the plane where the support structure 31 is located and the support structure 31 share the superimposed area A and are separate in non-superimposed areas B. In FIG. 3, on the plane where the clamping structure 32 is located, the non-superimposed areas B are located on two sides of the superimposed area A. Of course, the non-superimposed areas B may also be located on a same side of the superimposed area A. The location of the non-superimposed areas is not limited in the embodiments of the application.

In the fixture shown in FIG. 3, an extension direction of the clamping structure 32 and an extension direction of the support structure 31 form a preset included angle. For example, when the preset included angle is 90 degrees, the extension direction of the clamping structure 32 and the extension direction of the support structure 31 are perpendicular to each other. Of course, the value of the preset included angle may be determined upon actual situations, and is not limited in the embodiments of the disclosure.

Further, the fixture is internally provided with a first hollowed structure 321. The first hollowed structure 321 is located in the support structure 31 in the non-superimposed area B and/or the clamping structure 32 in the non-superimposed area B. As shown in FIG. 3, the first hollowed structure 321 is located in the clamping structure 32 in the non-superimposed area B. As shown in FIG. 4, the first hollowed structure 321 is located in the support structure 31 in the non-superimposed area B. While in the same fixture, the first hollowed structure 321 may be provided on the clamping structure 32 located in the non-superimposed area B, and the first hollowed structure 321 may also be provided on the support structure 31 located in the non-superimposed area B. No matter whether the first hollowed structure 321 is provided on the clamping structure 32 or the first hollowed structure 321 is provided on the support structure 31, or the first hollowed structure 321 is provided on the clamping structure 32 and the first hollowed structure 321 is provided on the support structure 31, the number of the first hollowed structure 321 in the clamping structure 32 or in the support structure 31 is greater than or equal to 1. The specific number of the first hollowed structure 321 may be selected upon actual situations, and is not limited in the embodiments of the application.

In the fixture, the support structure 31 needs to support the clamping structure 32, so the support structure 31 is made of a rigid material, for example, aluminum alloys. The clamping structure 32 needs to clamp the to-be-sputtered substrate, so the rigidity thereof may be not too high to avoid damage to the to-be-sputtered substrate. The clamping structure 32 is usually made of the thermal insulating materials, which usually have proper rigidity and may fix the to-be-sputtered substrate without damaging the same. For example, the thermal insulating material may be polyether-ether-ketone, which has a heat conduction coefficient of 0.25 W/m·K at 20° C.

According to the embodiments of the disclosure, in the fixture, the first hollowed structure 321 is provided on the support structure 31 located in the non-superimposed area B and/or the clamping structure 32 located in the non-superimposed area B, such that a part of an area on the to-be-sputtered substrate covered by the fixture may be exposed via the first hollowed structure 321 when the fixture holds the to-be-sputtered substrate, so as to reduce the area of the to-be-sputtered substrate covered by the fixture. When the to-be-sputtered substrate is sputtered in a sputtering device, the heat from the sputtering device may be transmitted to the to-be-sputtered substrate via the first hollowed structure 321, thereby increasing the film-forming temperature in the area of the to-be-sputtered substrate covered by the fixture in the sputtering process, improving the quality of a film formed in the area of the to-be-sputtered substrate covered by the fixture, and further improving the product quality and yield.

For example, when the data line and the signal line are manufactured by a metal material in the to-be-sputtered substrate, the metal material may be one or more of Al, Cu, Mo and Ti. When the fixture is not internally provided with the first hollowed structure 321, the low film-forming temperature in the area of the to-be-sputtered substrate covered by the fixture results in large resistance of the data line and the signal line in this area, such that it fails to manufacture relative thin data line and signal line in this area, which is not conducive to the development of products with a high-resolution ratio. When the fixture is internally provided with the first hollowed structure 321, the film-forming temperature in the area of the to-be-sputtered substrate covered by the fixture is increased, and then the resistance of the data line and the signal line in the corresponding area is lowered, such that thinner data line and signal line may be obtained, which is conducive to the development of products with a high resolution and improves product quality.

In the case of a relatively low film-forming temperature in the film forming process, the obtained film layer is loose, and tends to generate small particles when receiving impact in other subsequent process procedures. The generation of the small particles results in problems, for example, a short circuit between a scanning line and the data line in the to-be-sputtered substrate, a short circuit between the data line and a public electrode, etc. Therefore, the first hollowed structure 321 is configured to increase the film-forming temperature in the area of the to-be-sputtered substrate covered by the fixture, such that the formed film layer is compact and does not generate small particles which result in a short circuit between the scanning line and the data line and between the data line and the public electrode, thereby avoiding the problems, for example, a short circuit between the scanning line and the data line and between the data line in the area of the to-be-sputtered substrate covered by the fixture, and a short circuit between the data line and the public electrode. Thus, the product yield is improved.

In addition, when metal semiconductor oxides are formed in the to-be-sputtered substrate, for example, when the IGZO film layer is formed in the to-be-sputtered substrate, if the fixture is not internally provided with the first hollowed structure 321, the area of the to-be-sputtered substrate covered by the fixture has a low film-forming temperature and obtains a poor film because of being blocked by the fixture, and the film layer in this area is particularly prone to becoming a conductor, so that a transistor formed in this area is opened at very low voltage, resulting in uneven brightness at the position of the finally produced display panel covered by the fixture and affecting the product yield. After the first hollowed structure 321 is provided on the fixture and when the IGZO film layer is formed on the to-be-sputtered substrate, the heat in the sputtering device is transmitted to the to-be-sputtered substrate via the first hollowed structure 321 in the fixture, thereby increasing the film-forming temperature in the area of the to-be-sputtered substrate covered by the fixture. Therefore, the film in this area is not easy to become a conductor, avoiding the phenomenon of uneven brightness in the area of the display panel covered by the fixture, and further enhancing the product yield.

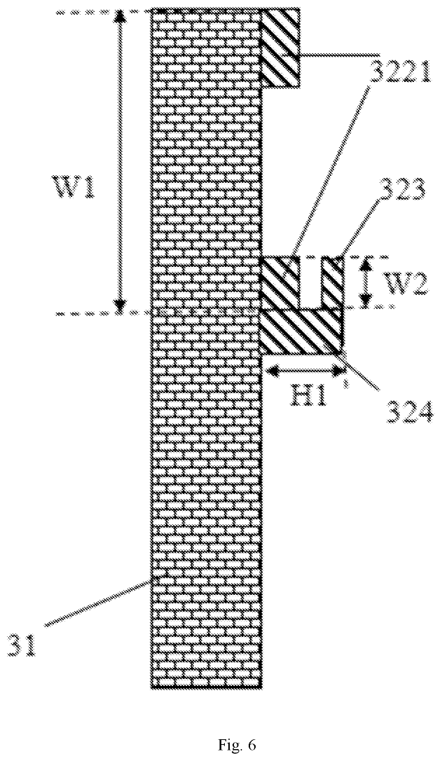

According to the embodiments of the disclosure, as shown in FIG. 5 and FIG. 6, the clamping structure 32 comprises a first clamping component 322, a second clamping component 323, and a connecting component 324 which connects the first clamping component 322 and the second clamping component 323; the plane where the first clamping component 322 is located is parallel to the plane where the second clamping component 323 is located, and the plane where the first clamping component 322 is located and the plane where the second clamping component 323 is located are both perpendicular to the plane where the connecting component 324 is located.

According to the embodiments of the disclosure, FIG. 5 is a lateral view of the fixture shown in FIG. 3, and FIG. 6 is a lateral view of the fixture shown in FIG. 4. In the clamping structure 32, the plane where the first clamping component 322 is located and the plane where the second clamping component 323 is located are parallel to each other, the plane where the first clamping component 322 is perpendicular to the plane where the connecting component 324 is located, and the plane where the second clamping component 323 is located is also perpendicular to the plane where the connecting component 324 is located. The first clamping component 322, the second clamping component 323 and the connecting component 324 form a groove structure in the extension direction of the clamping structure 32. When sputtering is performed on the to-be-sputtered substrate, the to-be-sputtered substrate is clamped and fixed in the groove structure of the clamping structure 32, preventing the to-be-sputtered substrate from moving during sputtering.

According to an optional embodiment of the disclosure, as shown in FIG. 3, the first hollowed structure 321 is located in the clamping structure 32, and penetrates through the first clamping component 322 in the clamping structure 32.

Specifically, when the first hollowed structure 321 is located in the clamping structure 32, the first hollowed structure 321 is arranged in the first clamping component 322 of the clamping structure 32, and the first hollowed structure 321 penetrates through the first clamping component 322. The arrangement of the first hollowed structure 321 in the clamping structure 32 reduces the contact area between the clamping structure 32 and the to-be-sputtered substrate, thereby increasing the film-forming temperature in the area of the to-be-sputtered substrate covered by the clamping structure 32, and improving the quality of the formed film.

According to the embodiments of the disclosure, a width W1 of the first clamping component 322 is greater than a width W2 of the second clamping component 323 in an extension direction of the support structure 31.

According to the embodiments of the disclosure, in the extension direction of the support structure 31, the width W1 of the first clamping component 322 is set to be greater than the width W2 of the second clamping component 323, that is, the width W2 of the second clamping component 323 is less than the width W1 of the first clamping component 322, thereby facilitating placement of the to-be-sputtered substrate in the groove structure formed by the first clamping component 322, the second clamping component 323 and the connecting component 324.

Specifically, in the extension direction of the support structure 31, the width W1 of the first clamping component 322 is 10 mm-30 mm, and the width W2 of the second clamping component 323 is 1 mm-5 mm; and along the direction perpendicular to the plane where the first clamping component 322 is located, a thickness H1 of the connecting component 324 is 1 mm-5 mm.

According to the embodiment of the disclosure, a too large width W1 of the first clamping component 322 may increase the area of the to-be-sputtered substrate covered by the first clamping component 322, affecting the film-forming temperature of the to-be-sputtered substrate, and that a too small width W1 of the first clamping component 322 is not conducive to providing the first hollowed structure 321 in the first clamping component 322. According to the embodiments of the application, the width W1 of the first clamping component 322 is set to be 10 mm-30 mm, such that the first clamping component 322 does not cover the to-be-sputtered substrate in a large area. Therefore, it is ensured that the film-forming temperature of the to-be-sputtered substrate is not affected, and the first clamping component 322 has sufficient inner space to arrange the first hollowed structure 321 to enhance the hollowing rate of the fixture. For example, the width W1 of the first clamping component 322 may be set to be equal to 25 mm.

Moreover, during arrangement of the second clamping component 323, when the width W2 of the second clamping component 323 is set to too large, it is difficult to place the to-be-sputtered substrate in the groove structure formed by the first clamping component 322, the second clamping component 323 and the connecting component 324; and when the width W2 of the second clamping component 323 is set to too small, the to-be-sputtered substrate faces the risk of slipping out of the groove structure, affecting the safety of the to-be-sputtered substrate. Therefore, according to the embodiments of the application, by setting the width W2 of the second clamping components 323 to 1 mm-5 mm, the to-be-sputtered substrate may be conveniently placed in the groove structure formed by the first clamping component 322, the second clamping component 323 and the connecting component 324, and this width may limit the to-be-sputtered substrate in the groove structure to ensure the safety of the to-be-sputtered substrate.

In addition, along the direction perpendicular to the plane where the first clamping component 322 is located, the to-be-sputtered substrate tends to slide in the groove structure and is unstable when the thickness H1 of the connecting component 324 is set to too large, and it fails to place the to-be-sputtered substrate in the groove structure, that is, it fails to fix the to-be-sputtered substrate, when the thickness H1 of the connecting component 324 is set to too small. Therefore, according to the embodiments of the application, when the thickness H1 of the connecting component 324 is set to 1 mm-5 mm along the direction perpendicular to the plane where the first clamping component 322 is located, the to-be-sputtered substrate may be placed in the groove structure, and the to-be-sputtered substrate does not have a very large space for movement thereby ensuring the stability of the to-be-sputtered substrate in the groove structure.

As shown in FIG. 3 and FIG. 4, when the extension direction of the clamping structure 32 and the extension direction of the support structure 31 are perpendicular to each other, the first clamping component 322, the second clamping component 323 and the connecting component 324 all have a length L along the extension direction of the clamping structure 32, wherein L is 65 mm-195 mm.

According to the embodiments of the application, the film-forming temperature in the area of the to-be-sputtered substrate covered by the fixture may be increased by changing the dimensions of the fixture. For example, the width of the first clamping component 322 in the clamping structure 32 is reduced in the extension direction of the support structure 31, or the length of the first clamping component 322 in the clamping structure 32 is reduced in the extension direction of the clamping structure 32. A reduction of the fixture dimensions decreases the area of the to-be-sputtered substrate covered by the fixture, thereby increasing the film-forming temperature in the area of the to-be-sputtered substrate covered by the fixture and improving the quality of the formed film.

According to another optional embodiment of the disclosure, as shown in FIG. 4 and FIG. 6, the first hollowed structure 321 is located in the support structure 31, wherein, the first clamping component 322 comprises at least one clamping sub-component 3221, each of the clamping sub-components 3221 is connected with the support structure 31, and the orthographic projection of the each of the clamping sub-components 3221 on the plane where the support structure 31 is located is not superimposed with the first hollowed area 321 in the support structure 31.

Specifically, the first hollowed structure 321 may be arranged in the support structure 31. In the fixture, the first clamping component 322 comprises at least one clamping sub-component 3221, and the orthographic projection of each of the clamping sub-components 3221 on the plane where the support structure 31 is located is not superimposed with the first hollowed structure 321 in the support structure 31. When the clamping structure 32 clamps the to-be-sputtered substrate, each of the clamping sub-components 3221 contacts the to-be-sputtered substrate, while a structure between adjacent clamping sub-components 3221 is removed. When the fixture as shown in FIG. 4 is used to hold the to-be-sputtered substrate, not only the to-be-sputtered substrate corresponding to the first hollowed structure 321 on the support structure 31 is not blocked by the fixture, but also the to-be-sputtered substrate corresponding to the area between the adjacent clamping sub-components 3221 is not blocked by the fixture, thereby increasing the film-forming temperature at a position of the to-be-sputtered substrate corresponding to the fixture, and improving the quality of the formed film.

It should be noted that, in the planar diagram of the fixture as shown in FIG. 4, a structure in the clamping structure 32 closer to the connecting component 324 is marked as the clamping sub-component 3221 to allow readers to see more clearly the position relationship between two clamping sub-components 3221 of the first clamping component 322. In the planar diagram of an actual fixture, this structure actually represents the second clamping component 323, and the orthographic projection of the second clamping component 323 on the plane where the first clamping component 322 is located covers the clamping sub-component 3221 connected to the connecting component 324.

Wherein, the extension direction of each of the clamping sub-components 3221 is parallel or perpendicular to the extension direction of the support structure 31.

Specifically, the extension direction of each of the clamping sub-components 3221 may be parallel or perpendicular to the extension direction of the support structure 31. Wherein, when the extension direction of each of the clamping sub-components 3221 is parallel to the extension direction of the support structure 31, the width W1 of the first clamping component 322 is 10 mm-30 mm along the extension direction of the support structure 31. The width W1 of the first clamping component 322 refers to: the sum of the widths of two most distant clamping sub-components 3221 in the first clamping component 322 and the distance between the most distant clamping sub-components 3221, along the extension direction of the support structure 31. At this time, the length L of each of the clamping sub-components 3221 is 65 mm-195 mm in the extension direction of the clamping sub-components 3221.

According to the embodiments of the disclosure, the first clamping component 322 comprises at least two clamping sub-components 3221. On the plane where the support structure 31 is located, all clamping sub-components 3221 of the first clamping component 322 are located on the same side of the first hollowed structure 321, or first clamping sub-components of the first clamping component 322 and second clamping sub-components other than the first clamping sub-components in the first clamping component 322 are located on different sides of the first hollowed structure 321.

As shown in FIG. 4, a first side, namely the left side, of the first hollowed structure 321, a second side, namely the right side, of the first hollowed structure 321, a third side, namely the upper side, of the first hollowed structure 321, and a fourth side, namely the lower side, of the first hollowed structure 321 exist on the plane where the support structure 31 is located. When the first clamping component 322 comprises at least two clamping sub-components 3221, on the plane where the support structure 31 is located, all clamping sub-components 3221 of the first clamping component 322 are located on the same side of the first hollowed structure 321, that is, all the clamping sub-components 3221 are located on the first side of the first hollowed structure 321, or all the clamping sub-components 3221 are simultaneously located on the second side of the first hollowed structure 321, or all the clamping sub-components 3221 are located on the third side of the first hollowed structure 321, or all the clamping sub-components 3221 are located on the fourth side of the first hollowed structure 321.

Or, the first clamping component 322 comprises the first clamping sub-components and the second clamping sub-components other than the first clamping sub-components, and the first clamping sub-components and the second clamping sub-components are located on different sides of the first hollowed structure 321. For example, when the first clamping sub-components are located on the first side of the first hollowed structure 321, the second clamping sub-components may be located on any one side other than the first side of the first hollowed structure 321, or the second clamping sub-components may also be located on any two sides other than the first side of the first hollowed structure 321, or the second clamping sub-components may also be distributed on the second, third and fourth sides of the first hollowed structure 321. When the first clamping sub-components are located on the second side of the first hollowed structure 321, the second clamping sub-components may be located on any one side other than the second side of the first hollowed structure 321, or the second clamping sub-components may be located on any two sides other than the second side of the first hollowed structure 321, or the second clamping sub-components may also be distributed on the first side, the third side and the fourth side of the first hollowed structure 321. When the first clamping sub-components are located on the third side of the first hollowed structure 321, the second clamping sub-components may be located on any one side other than the third side of the first hollowed structure 321, or the second clamping sub-components may also be located on any two sides other than the third side of the first hollowed structure 321, or the second clamping sub-components may also be distributed on the first side, the second side and the fourth side of the first hollowed structure 321. When the first clamping sub-component is located on the fourth side of the first hollowed structure 321, the second clamping sub-components may be located on any one side other than the first side of the first hollowed structure 321, or the second clamping sub-components may be located on any two sides other than the fourth side of the first hollowed structure 321, or the second clamping sub-components may also be distributed on the first side, the second side and the third side of the first hollowed structure 321.

For example, as shown in FIG. 4, the first clamping component 322 comprises two clamping sub-components, wherein one is a first clamping sub-component and the other is a second clamping sub-component, and the first clamping sub-component and the second clamping sub-component are located on different sides of the first hollowed structure 321. Specifically, the first clamping sub-component is located on the third side of the first hollowed structure 321, namely the upper side of the first hollowed structure 321, and the second clamping sub-component is located on the fourth side of the first hollowed structure 321, namely the lower side of the first hollowed structure 321.

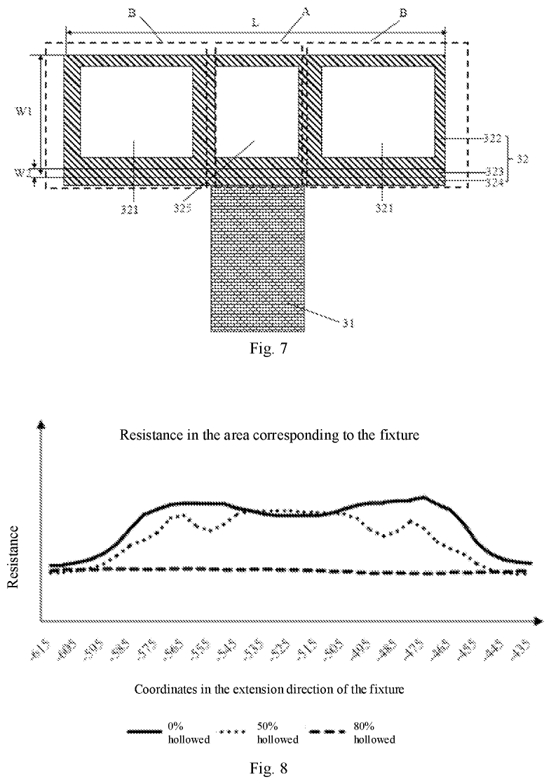

Further, as shown in FIG. 7, the support structure 31 and the clamping structure 32 which are located in the superimposed area A have a second hollowed structure 325, and the second hollowed structure 325 penetrates through the support structure 31 and the clamping structure 32.

According to the embodiments of the disclosure, the orthographic projection of the clamping structure 32 on the plane where the support structure 31 and the support structure 31 share the superimposed area A. In the superimposed area A, the support structure 31 and the clamping structure 32 have the second hollowed structure 325, and the second hollowed structure 325 penetrates through the support structure 31 and the clamping structure 32, specifically, penetrates through the first clamping component 322 in the clamping structure 32.

From FIG. 7 it may be known that, at this time, the orthographic projection of the clamping structure 32 on the plane where the support structure 31 is located and the support structure 31 share the superimposed area A and are separate in the non-superimposed areas B. The second hollowed structure 325 is arranged in the superimposed area A, and the first hollowed structure 321 is arranged in the non-superimposed areas B, that is, the fixture has the first hollowed structure 321 and the second hollowed structure 325 at the same time, thus increasing the hollowing rate of the fixture, further increasing the film-forming temperature of the area of the to-be-sputtered substrate covered by the fixture when film forming is performed on the to-be-sputtered substrate, and improving the quality of the formed film.

Specifically, the hollowing rate of the fixture is greater than or equal to 50% and less than 100%.

According to the embodiments of the disclosure, the hollowing rate of the fixture refers to: in the fixture, the ratio of the area of the first hollowed area 321, or the ratio of areas of the first hollowed structure 321 and the second hollowed structure 325, to the area of the to-be-sputtered substrate. The hollowing rate of the area of the fixture covered by the to-be-sputtered substrate is greater than or equal to 50% and less than 100% when the to-be-sputtered substrate is subject to sputtering. The hollowing rate of the fixture influences the film-forming temperature in the area of the to-be-sputtered substrate covered by the fixture. A higher hollowing rate leads to a higher film-forming temperature in the area of the to-be-sputtered substrate covered by the fixture, and a higher film-forming temperature means higher quality of the formed form.

For example, films are formed on the to-be-sputtered substrate using fixtures with different hollowing rates, as shown in FIG. 8. In FIG. 8, the horizontal ordinates represent coordinate values in the extension direction of the fixture, and the longitudinal axis indicates the resistance of film layers. It can be seen that, the resistance of the film layer formed at the position covered by the fixture with a 50% hollowing rate is lower than the resistance of the film layer formed at the position covered by the fixture with a 0% hollowing rate, and the resistance of the film layer formed at a position covered by the fixture with an 80% hollowing rate is obviously reduced, and is less than both the resistance of the film layer formed at the position covered by the fixture with a 50% hollowing rate and the resistance of the film layer formed at the position covered by the fixture with a 0% hollowing rate. When the film layer is used to form the data line or the signal line in the to-be-sputtered substrate, a thinner data line or signal line may be manufactured as the resistance of the film layer becomes smaller, which is conducive to the development of products with a higher resolution ratio and improves product quality.

In addition, in the related art, since the fixture has no hollowed structure inside, the film-forming temperature is low at the position of the to-be-sputtered corresponding to the fixture, so that the film formed at this position has poor quality. To avoid an influence on the quality of the display panel subsequently formed by the to-be-sputtered substrate, the part of to-be-sputtered substrate corresponding to the fixture is usually discarded, so the utilization rate of the to-be-sputtered substrate is low, only 94.9%. When first hollowed structure 321 is provided on the fixture and/or the second hollowed structure 325, the film-forming temperature at the position of the to-be-sputtered substrate corresponding to the fixture may be increased, so the quality of the film formed at the position corresponding to the fixture is not affected by the over-low film-forming temperature. Therefore, the part of to-be-sputtered substrate corresponding to the fixture is capable of being used normally, thus increasing the utilization rate of the to-be-sputtered substrate. The utilization rate of the to-be-sputtered substrate may reach 97.5%.

According to the embodiment of the disclosure, the first hollowed structure 321 and the second hollowed structure 325 are both closed structures.

The first hollowed structure 321 and the second hollowed structure 325 are both closed structures, that is, the first hollowed structure 321 and the second hollowed structure 325 may be cylindrical, rectangular, hexagonal, etc. The specific shapes are not limited in the embodiments of the disclosure. The shapes of the first hollowed structure 321 and the second hollowed structure 325 may be identical or different; when the fixture comprises a plurality of first hollowed structures 321, the shapes of the first hollowed structures 321 may be identical or different; and when the fixture comprises a plurality of second hollowed structures 325, the shapes of the second hollowed structures 325 may be identical or different. The shapes of the first hollowed structure and the second hollowed structure are not limited in the embodiments of the application.

Wherein, when the first hollowed structure 321 or the second hollowed structure 325 is cylindrical, the diameter of the cylindrical body may be 10 mm. The diameter of the cylindrical body may be set according to the specific dimensions of the support structure 31 and the clamping structure 32, and is not limited in the embodiments of the disclosure.

Optionally, during fixture manufacturing, the film-forming temperature at the position of the to-be-sputtered substrate corresponding to the fixture may be increased by enhancing the hollowing rate of the fixture and reducing the fixture dimensions at the same time, thus improving the quality of the formed film.

According to the embodiments of the disclosure, in the fixture, the first hollowed structure is arranged on the support structure located in the non-superimposed area and/or the clamping structure located in the non-superimposed area, such that a part of area of the to-be-sputtered substrate covered by the fixture may be exposed via the first hollowed area when the fixture holds the to-be-sputtered substrate, so as to reduce the area of the to-be-sputtered substrate covered by the fixture, thereby increasing the film-forming temperature in the area of the to-be-sputtered substrate covered by the fixture in the sputtering process, improving the quality of the film formed in the area of the to-be-sputtered substrate covered by the fixture, and further improving the product quality and yield.

The embodiments of the disclosure provide a tray, comprising a tray body 91 and a plurality of aforementioned fixtures 30 arranged on the tray body 91.

According to the embodiments of the application, the specific structure of the fixtures 30 is as described in Embodiment 1 and is not repeatedly described here.

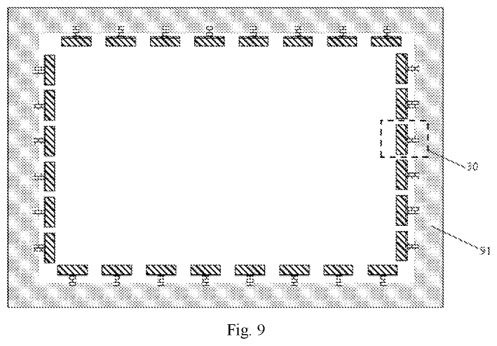

As shown in FIG. 9, a plurality of fixtures 30 are arranged on the tray body 91. The fixtures 30 are located on the tray body 91 and distributed along four sides of the tray body 91. The tray body 91 provided with the fixtures 30 is configured to bear and fix a to-be-sputtered substrate when sputtering process is performed on the to-be-sputtered substrate. The number of the fixtures 30 on the tray body 91 may be set upon actual demands, and is not limited in the embodiments of the disclosure.

The embodiments of the disclosure further provide a sputtering system, comprising a sputtering device and the tray.

According to the embodiment of the disclosure, the sputtering system comprises the sputtering device and the tray. When the sputtering process is performed, the to-be-sputtered substrate is placed on the tray body 91. After the to-be-sputtered substrate is fixed by the plurality of fixtures 30 on the tray body 91, the tray fixed with the to-be-sputtered substrate is placed in the sputtering device, and then the to-be-sputtered substrate is subject to sputtering. After sputtering the to-be-sputtered substrate is completed, the tray is moved out of the sputtering device, and then the to-be-sputtered substrate treated by the sputtering process is taken off from the tray to complete subsequent procedures.

According to the embodiments of the application, in the fixture, the first hollowed structure is arranged in the support structure located in the non-superimposed area and/or the clamping structure located in the non-superimposed area, such that a part of area of the to-be-sputtered substrate covered by the fixture may be exposed via the first hollowed area when the fixture holds the to-be-sputtered substrate, so as to reduce the area of the to-be-sputtered substrate covered by the fixture, thereby increasing the film-forming temperature in the area of the to-be-sputtered substrate covered by the fixture in the sputtering process, improving the quality of the film formed in the area of the to-be-sputtered substrate covered by the fixture, and further improving the product quality and yield.

Despite the description of the preferred embodiments of the application, those skilled in the art are able to make additional variations and amendments to those embodiments when they know the basic innovative concept. Therefore, the appended claims are intended to be explained as including the preferred embodiments and all variations and amendments that fall within the scope of the embodiments of the application.

Finally, it should also be noted that, in thus text, terms “comprise”, “include” or any other variations thereof refer to non-exclusive inclusion, so a process, method, article or terminal device comprising a series of elements not only comprise those elements listed, but also comprise other elements that are not explicitly listed or inherent elements of the process, method, article or terminal device. In the absence of more restrictions, a process, method, article or terminal device comprising an element defined by “one” shall not exclusive of other identical elements.

The above embodiments are merely specific ones of the application, and should not be construed as limiting the protective scope of the application. Those ordinarily skilled in the art may easily make variations and amendments to the above embodiments within the scope of the invention, and all those variations and amendments shall fall within the protective scope of the application. Therefore, the protective scope of the disclosure shall be subject to that of the claims.

1. A fixture, comprising a support structure and a clamping structure connected with each other, wherein the clamping structure is configured to clamp a to-be-sputtered substrate; both a superimposed area and a non-superimposed area exist between an orthographic projection of the clamping structure on a plane where the support structure is located and the support structure;
wherein the support structure located in the non-superimposed area and/or the clamping structure located in the non-superimposed area has a first hollowed structure.

2. The fixture according to claim 1, wherein the clamping structure comprises a first clamping component, a second clamping component, and a connecting component which connects the first clamping component and the second clamping component; a plane where the first clamping component is located is parallel to a plane where the second clamping component is located, and the plane where the first clamping component is located and the plane where the second clamping component is located are both perpendicular to a plane where the connecting component is located.

3. The fixture according to claim 2, wherein the first hollowed structure is located in the clamping structure, and penetrates through the first clamping component in the clamping structure.

4. The fixture according to claim 2, wherein the first hollowed structure is located in the support structure;
wherein, the first clamping component comprises at least one clamping sub-component, each of the clamping sub-components is connected with the support structure, and an orthographic projection of each of the clamping sub-components on the plane where the support structure is located is not superimposed with the first hollowed structure in the support structure.

5. The fixture according to claim 4, wherein an extension direction of each of the clamping sub-components is parallel or perpendicular to an extension direction of the support structure.

6. The fixture according to claim 4, wherein the first clamping component comprises at least two clamping sub-components, and on the plane where the support structure is located, all the clamping sub-components of the first clamping component are located on a same side of the first hollowed structure, or the first clamping sub-components of the first clamping component and second clamping sub-components other than the first clamping sub-components in the first clamping component are located on different sides of the first hollowed structure.

7. The fixture according to claim 1, wherein the support structure and the clamping structure which are located in the superimposed area have a second hollowed structure, and the second hollowed structure penetrates through the support structure and the clamping structure.

8. The fixture according to claim 1, wherein a hollowing rate of the fixture is greater than or equal to 50% and less than 100%.

9. The fixture according to claim 2, wherein a width of the first clamping component is greater than a width of the second clamping component in the extension direction of the support structure.

10. The fixture according to claim 9, wherein in the extension direction of the support structure, the width of the first clamping component is 10 mm-30 mm, and the width of the second clamping component is 1 mm-5 mm; and,
a thickness of the connecting component is 1 mm-5 mm along a direction perpendicular to the plane where the first clamping component is located.

11. The fixture according to claim 7, wherein the first hollowed structure and the second hollowed structure are both closed structures.

12. A tray, comprising a plurality of fixtures, wherein the fixture comprising a support structure and a clamping structure connected with each other, wherein the clamping structure is configured to clamp a to-be-sputtered substrate; both a superimposed area and a non-superimposed area exist between an orthographic projection of the clamping structure on a plane where the support structure is located and the support structure wherein the support structure located in the non-superimposed area and/or the clamping structure located in the non-superimposed area has a first hollowed structure.

13. The tray according to claim 12, wherein the clamping structure comprises a first clamping component, a second clamping component, and a connecting component which connects the first clamping component and the second clamping component; a plane where the first clamping component is located is parallel to a plane where the second clamping component is located, and the plane where the first clamping component is located and the plane where the second clamping component is located are both perpendicular to a plane where the connecting component is located.

14. The tray according to claim 13, wherein the first hollowed structure is located in the clamping structure, and penetrates through the first clamping component in the clamping structure.

15. The tray according to claim 13, wherein the first hollowed structure is located in the support structure;
wherein, the first clamping component comprises at least one clamping sub-component, each of the clamping sub-components is connected with the support structure, and an orthographic projection of each of the clamping sub-components on the plane where the support structure is located is not superimposed with the first hollowed structure in the support structure.

16. The tray according to claim 15, wherein an extension direction of each of the clamping sub-components is parallel or perpendicular to an extension direction of the support structure.

17. The tray according to claim 15, wherein the first clamping component comprises at least two clamping sub-components, and on the plane where the support structure is located, all the clamping sub-components of the first clamping component are located on a same side of the first hollowed structure, or the first clamping sub-components of the first clamping component and second clamping sub-components other than the first clamping sub-components in the first clamping component are located on different sides of the first hollowed structure.

18. The tray according to claim 12, wherein the support structure and the clamping structure which are located in the superimposed area have a second hollowed structure, and the second hollowed structure penetrates through the support structure and the clamping structure.

19. The tray according to claim 12, wherein a hollowing rate of the fixture is greater than or equal to 50% and less than 100%.

20. A sputtering system, comprising a sputtering device and the tray according to claim 12.
